(19) United States
(12) Patent Application Publication
(10) Pub. No.: US 2006/0251972 A1
(43) Pub. Date: Nov. 9, 2006

(54) Flexible photomask for photolithography, method of manufacturing the same, and micropatterning method using the same

(76) Inventor: Tae-Woo Lee, Seoul (KR)

Correspondence Address: ROBERT E. BUSHNELL, 1522 K STREET NW, SUITE 300, WASHINGTON, DC, 20005-1202, US

(21) Appl. No.: 11/324,211

(22) Filed: Jan. 3, 2006

(30) Foreign Application Priority Data
Jan. 4, 2005 (KR) 10-2005-0000380

(51) Int. Cl. G03F 1/00

(52) U.S. Cl. 430/5

(57) ABSTRACT

Provided are a flexible photomask for photolithography, a method of manufacturing the same, and a patterning method using the same. The flexible photomask is made of a light-transmissive elastomer and has a patterned surface.

### CLAIM OF PRIORITY

This application makes reference to, incorporates the same herein, and claims all benefits accruing under 35 U.S.C. §119 from an application for SOFT CONFORMABLE PHOTOMASK FOR PHOTOLITHOGRAPHY, PROCESS FOR PREPARING THE SAME, AND FINE PATTERING PROCESS USING THE SAME, earlier filed in the Korean Intellectual Property Office on the 4^{th} of Jan. 2005 and there duly assigned Serial No. 10-2005-0000380.

### BACKGROUND OF THE INVENTION

1. Field of the Invention

The present invention relates to a flexible photomask for photolithography, a method of manufacturing the same, and a patterning method using the same. More particularly, the present invention relates to a flexible photomask for photolithography made of a light-transmissive elastomer with a patterned surface, a method of manufacturing the same, and a patterning method for the same.

2. Related Art

Manufacturing of electrodes for display devices and semiconductors is performed by a photolithography process. Generally, the formation of a photoresist micropattern layer on a substrate is performed as follows. First, a photoresist layer is formed on a surface of a substrate, and a photomask having a masking pattern is placed on the top of the photoresist layer. When ultraviolet light, etc. is irradiated to the photoresist layer through the masking pattern, the solubility behavior of the photoresist material is modified in an exposed region of the photoresist layer, thereby forming a latent image which is a reproduction of the fine pattern of the photomask.

There are two types of photoresist: positive and negative type. For the former, when the solubility of photoresist is increased by exposure, the exposed region of the photoresist is dissolved in a developing solution. On the other hand, for the latter, the exposed region of photoresist is insoluble. Therefore, an unexposed portion of the photoresist is selectively removed by a developing solution. For both positive and negative type photoresists, a developing process uses the solubility difference between exposed and unexposed areas to form a latent image on a substrate.

Highly integrated semiconductor devices and electrodes of display devices, the demand for which has been rapidly increasing, requires higher resolution of the above-described patterning. Fabrication of most microelectronic devices such as display devices and semiconductor devices requires photolithographic patterning processes several to ten times. Since the photolithographic patterning process involves chemical etching steps that makes a surface of a photoresist layer rough, the fine pattern reproduced on the photoresist layer is less accurate than that of a photomask.

Another factor lowering the accuracy is incomplete contact between a photomask and a photoresist layer. This issue is especially critical when a flexible substrate is used in the photolithography.

### SUMMARY OF THE INVENTION

In view of the here and other problems in the photolithography process, the present invention provides a flexible photomask for photolithography capable of forming a high-resolution fine pattern on a photoresist layer, and a method of manufacturing the same.

The present invention also provides a micropatterning method using a photomask.

According to an aspect of the present invention, there is provided a flexible photomask for photolithography. The flexible photomask includes a mask layer and a surface pattern formed on one side of the mask layer. The mask layer of the photomask could be made of a light-transmissive elastomer.

The light-transmissive elastomer may have a glass transition temperature of less than room temperature and may be at least one selected from the group consisting of polydimethylsiloxane, nitrile rubber, acrylic rubber, polybutadiene, polyisoprene, butyl rubber, and poly(styrene-co-butadiene).

The patterned surface has a plurality of depressions [symbol] and prominences [symbol] .

The patterned surface could be made of the same material as the mask layer, or an opaque material that is a different material from the mask layer. An opaque layer may be further formed on depressions [symbol] or prominences [symbol] of the patterned surface.

The opaque layer may be a metal layer or an organic material layer.

The organic material layer maybe a low molecular weight layer, a polymer layer, a carbon black layer, or a silver paste layer.

A light absorption band of the organic material layer may be in the range from 200 nm to 450 nm.

The metal layer may be made of at least one metal selected from the group consisting of gold, silver, chromium, aluminum, nickel, platinum, palladium, titanium, and copper.

A thickness of the opaque layer may be in the range from 1 nm to 500 nm.

A pattern thickness of the patterned surface may be in the range from 100 nm to 1 μm.

According to another aspect of the present invention, there is provided a method of manufacturing a flexible photomask for photolithography. The method includes preparing a patterned master substrate; applying a mixture of an elastomer precursor and a crosslinking agent to the master substrate to induce polymerization; polymerizing the elastomer precursor, and separating the resultant mask from the master substrate.

The method may further include depositing a metal on a patterned surface of the mask; and removing a metal layer formed on prominences [symbol] of the patterned surface of the mask.

The method may further include applying an adhesive polymer solution, a carbon black paste, or a silver paste to prominences [symbol] of the patterned surface of the mask.

According to still another aspect of the present invention, there is provided a method of manufacturing a flexible photomask for photolithography, the method including forming a silicon-based elastomer layer, contacting a shadow mask to the elastomer layer, and depositing a metal or an organic material in vacuum.

According to yet another aspect of the present invention, there is provided a micropatterning method including forming a photoresist layer on a base substrate, contacting the patterned surface of the above-described flexible photomask to the photoresist layer, and forming a photoresist pattern by exposure.

The micropatterning method may further include forming a metal layer on the base substrate before forming a photoresist layer on the base substrate, and etching the metal layer and removing the photoresist pattern.

The base substrate may be made of glass, plastic, rubber, or elastomer. The base substrate may be made of a silicon-based elastomer.

The metal layer may include an adhesive promoter layer.

The metal layer may include a first layer and a second layer. The first layer may be an adhesive promoter layer made of Ti or Cr and having a thickness of 1 nm to 5 nm and the second layer may be a metal layer made of Au, Ag, Al, Pd, or Pt and having a thickness of 5 nm to 100 nm.

According to a further aspect of the present invention, there is provided an electrode for a display device including a fine pattern formed according to the above-described micropatterning method.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view illustrating a sequence of steps in a photolithography process;

FIG. 2 is a schematic sectional view illustrating a photomask with a polymer layer formed on the surface pattern;

FIG. 3A is a schematic view illustrating a sequence of steps in a photolithography process for forming a photoresist pattern;

FIG. 3B is a schematic view illustrating a photolithography process for forming a metal pattern on a flexible substrate;

FIG. 4A illustrates an example of a flexible photomask;

FIG. 4B illustrates an example of a flexible photomask with an opaque layer formed on the surface of the promineneces;

FIG. 4C illustrates an example of a flexible photomask with an opaque layer formed on the surface of the depressions;

FIG. 5 is a first example of an optical microscopic image of a metal pattern obtained with the use of a flexible photomask;

FIG. 6 is a second example of an optical microscopic image of a metal pattern obtained with the use of the flexible photomask;

FIG. 7 is an example of optical microscopic image of an electrode for an organic electroluminescent device obtained with the use of the flexible photomask;

FIG. 8 is a schematic sectional view illustrating an organic electroluminescent device constructed as a first embodiment of the present invention;

FIG. 9 is a schematic sectional view illustrating an organic electroluminescent device constructed as a second embodiment of the present invention;

FIG. 10 is a schematic sectional view illustrating an organic electroluminescent device constructed as a third embodiment of the present invention; and

FIG. 11 is a schematic sectional view illustrating an organic electroluminescent device constructed as a fourth embodiment of the present invention.

### DETAILED DESCRIPTION OF THE INVENTION

The present invention will now be described in detail with reference to the accompanying drawings, in which exemplary embodiments of the invention are shown.

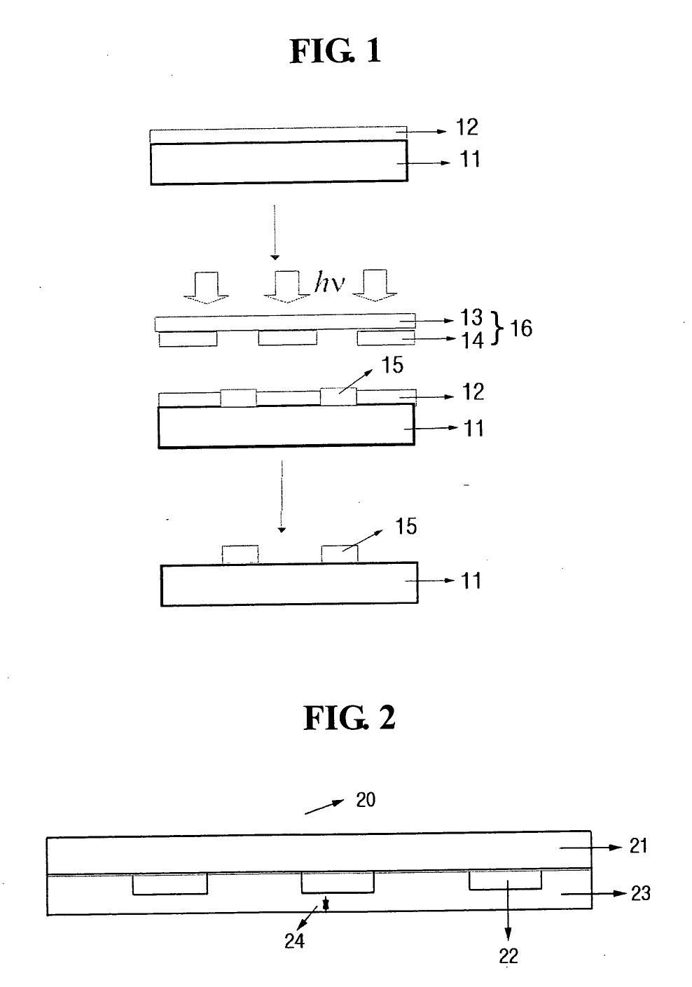

A photolithography process is shown in FIG. 1. A photoresist layer 12 is formed on a substrate 11, and a photomask 16 is placed on the top of the photoresist layer 12. Ultraviolet light is exposed to the photoresist layer 12 through the photomask 16. For the negative type photoresist, the exposed portion 15 becomes insoluble, and after developing process, the portion 15 remains as a photoresist pattern. The contact between a photoresist layer 12 and a photomask 16 is induced by vacuum or pressure. However, there is a problem in that the contact between the photoresist layer 12 and the photomask 16 is not complete. If photomask is made of a hard substrate 13 on which metal layer 14 being made of chromium, etc. is formed, even when vacuum or pressure is applied to the photomask 16 and the photoresist layer 12 during the exposure, there exits a gap between the photomask 16 and the photoresist layer 12 because of the hardness of the photomask 16. Lower resolution of the photoresist pattern is caused by this incomplete contact between the photomask 16 and the photoresist 12.

To solve this problem, U.S. Pat. No. 4,735,890, filed by Nakane et al, discloses a photomask coated with a polymer material to increase a contact between the photomask and a photoresist layer. According to the patent document, the contact between the photomask and the photoresist layer can be ensured to some extent. Referring to FIG. 2, however, a gap 24 is formed between a pattern 22 of a photomask 20 and a photoresist layer (not shown) due to a polymer layer 23 coated on a substrate plate 21 of the photomask 20, thereby lowering resolution and resulting in low integration and low working accuracy. In addition, the above-described techniques can not be applied to flexible substrates.

The present invention provides a photomask useful for a photolithography process. The photomask of the present invention is made of a flexible or soft material to secure a conformal contact with a surface of a photoresist layer. The flexible material may be a light-transmissive elastomer or polymer material that is capable of the conformal contact with a surface of a photoresist layer. A flexible photomask for photolithography made using a light-transmissive elastomer makes a complete contact with a photoresist layer formed on a substrate at a molecular level by Van der Waals interaction, which ensures a stronger contact between the patterns of the photomask and the photoresist layer.

A photomask made of a light-transmissive elastomer according to the principles of the present invention is in particular useful in performing a lithography process on a flexible substrate. That is, a photomask of the present invention not only can be used for lithography on a hard substrate such as a glass substrate, a high-quality silica glass substrate, or a hard plastic substrate, but also is particularly useful for lithography on a flexible substrate such as a flexible plastic substrate, an elastomer substrate, or a rubber substrate. The flexible substrate could be made of, for example, polyethylene terephthalate, polyethylene naphthalate, polyvinylalcohol, polydimethylsiloxane, polycarbonate, polyester, polyestersulfonate, polysulfonate, polyacrylate, fluorinated polyimide, fluorinated resin, polyacryl, polyepoxy, polyethylene, polystyrene, polyvinylchloride, polyvinylbutyral, polyacetal, polyamide, polyamideimide, polyetherimine, polyphenylenesulfide, polyethersulfone, polyetherketone, polyphthalamide, polyethemitrile, polybenzimidazole, polymethyl(meth)acrylate, polymethacrylamide, epoxy resin, phenol resin, melamine resin, urea resin, nitrile rubber, acrylic rubber, polybutadiene, polyisoprene, butyl rubber, and poly(styrene-co-butadiene). A photolithography process for these flexible substrates is impractical without the photomask of the present invention, because defects such as cracks may be produced in an interface between a metal pattern formed on a substrate and a photoresist layer.

When a flexible photomask according to the present invention is used in the photolithography, defects such as cracks are not produced in an interface between a metal pattern formed through photolithography and a photoresist layer, because the photomask is made of a flexible material such as a light-transmissive elastomer. Therefore, a flexible ITO electrode pattern for a flexible display device or a metal pattern can be easily manufactured without occurrence of defects such as cracks.

A photomask according to the present invention is made of a flexible, light-transmissive elastomer. The photomask has a predetermined surface pattern. The predetermined surface pattern may be integrally formed on a basic mask layer of the photomask using a light-transmissive elastomer which is the same material used to make the photomask. Alternatively, the predetermined surface pattern may also be separately formed with a metal layer or an organic material layer on the surface of the basic mask layer. That is, an opaque pattern may also be formed on a flat surface of a mask layer made of a light-transmissive elastomer.

A light-transmissive elastomer for a photomask of the present invention may be a polymer with a glass transition temperature below room temperature, for example, polydimethylsiloxane (hereinafter, referred to as PDMS), a nitrile rubber, an acrylic rubber, polybutadiene, polyisoprene, a butyl rubber, poly(styrene-co-butadiene), etc. The elastomer that can be used in the present invention, however, is not limited to the above-illustrated examples. Since light such as ultraviolet light passes through a photomask during an exposure process to change the solubility of a photoresist layer, it is preferable that the material used to make a photomask of the present invention has a good light-transmissive characteristics. It is also particularly preferable that the material is capable of forming a Van der Waals interaction with a photoresist layer. PDMS is one of the preferable materials that satisfie all the above requirements.

A basic mask layer of a flexible photomask according to the present invention may be formed integrally with a surface pattern using a base material, i.e., a light-transmissive elastomer. In this case, the amount of light reaching a photoresist layer is controlled by a difference in the transmission through the surface patterns during an exposure process. Referring to FIG. 4A, light passing through depressions 37 [symbol] of a photomask 33 (refractive index >1.5) is reflected from an air layer that has a lower refractive index of 1.0. Therefore, the depressions 37 [symbol] of the photomask 33 exhibit lower light transmittance than prominences 38 [symbol] of the photomask 33 that makes contact with a photoresist layer (not shown). Thus, the difference in light transmittance during the exposure induces a solubility deviation of a photoresist layer. Such a solubility deviation of a photoresist layer enables negative or positive type photolithography during a subsequent developing and etching processes.

An opaque layer 36 such as a metal layer or an organic material layer may also be formed on a surface pattern of a photomask 33, as shown in FIGS. 4B and 4C. That is, an opaque layer may be formed on depressions 37 [symbol] or prominences 38 [symbol] of a surface pattern of a photomask. With respect to the photomask with a surface pattern as shown in FIG. 4A, the light transmittance of the prominences 38 [symbol] is higher than that of the depressions 37 [symbol] . On the other hand, for a photomask in which an opaque layer is formed on depressions 37 [symbol] or prominences 38 [symbol] of a surface pattern as shown in FIG. 4C or 4B, respectively, only a region of the surface pattern on which the opaque layer is not formed allows light such as ultraviolet light to pass through due to its higher light transmittance. In more detail, in a case where an opaque layer is formed on depressions 37 [symbol] of a surface pattern as shown in FIG. 4C, light can pass through prominences 38 of the surface pattern, whereas it cannot pass through the depressions 37. Such a difference in light transmittance is because the prominences of the surface pattern are made of a light-transmissive elastomer, while the depressions 37 are coated with an opaque material. This pattern induces a solubility deviation for a developing solution between an exposed area and an unexposed area of the photoresist layer. In this case, a metal layer or an organic material layer may be formed as an opaque layer on depressions 37 [symbol] . A metal layer is preferable.

An opaque layer may also be formed on prominences 38 [symbol] of a surface pattern of a photomask as shown in FIG. 4B. In this case, while light can pass through depressions 37 [symbol] of the surface pattern, it can not pass through the prominences 38 [symbol] . Such a difference in light transmittance induces a solubility deviation between an exposed area and an unexposed area of the photoresist layer.

A metal for an opaque layer may be an opaque metal such as gold, silver, chromium, aluminum, nickel, platinum, palladium, titanium, and copper. An organic material layer may be made of a low molecular weight material, a polymer, a carbon black, or a silver paste, which has an absorption band of 200 nm to 450 nm. Generally, a low molecular weight material denotes an organic material with a molecular weight of less than 10,000, while polymer denotes an organic material with a molecular weight of more than 10,000. The low molecular weight material may be, for example, a single molecule, or an oligomer consisting of several molecules. An organic material layer with low light transmittance is particularly preferable. Even when an opaque layer is formed on prominences 38 [symbol] of a photomask, a Van der Waals interaction between the photomask and a photoresist layer, which is a characteristic of the present invention, can be retained.

The thickness of an opaque layer formed on a flexible photomask maybe in the range from 1 nm to 500 nm. If the thickness of the opaque layer is less than 1 μm, opacity of the opaque layer may be insufficient. On the other hand, an opaque layer with a thickness above 500 nm is economically unpreferable.

A thickness of a light-transmissive elastomer pattern formed on a flexible photomask according to the present invention may be in the range from 100 nm to 1 μm, more preferably from 300 nm to 500 nm. If the thickness of the light-transmissive elastomer pattern is less than 100 nm, sagging may occur. On the other hand, if it exceeds 1 μm, pattern destruction may occur.

A method of manufacturing a flexible photomask according to the present invention will now be described.

A method of manufacturing a flexible photomask includes preparing a patterned master substrate, adding a mixture of an elastomer precursor and a crosslinking agent on the master substrate, forming a mask on the master substrate by polymerization of the elastomer precursor, and separating the mask from the master substrate.

In more detail, first, a patterned mater substrate is prepared. The master substrate may be a glass, a high-quality silica glass, a plastic, a silicon wafer, etc., and can be manufactured by a method commonly known in the art, for example, photolithography, e-beam lithography, nano-imprint lithography, molding, or two-photon lithography. The master substrate is placed in a container having a wide bottom such as petri dish in the manner that a pattern of the master substrate faces upward. Then, an elastomer precursor is applied to the master substrate in the container so that the master substrate is covered with the elastomer precursor. The elastomer precursor is cured at a temperature of 60 to 100° C., preferably at about 80° C., for 30 minutes or more, preferably for 1 to 2 hours, to induce polymerization of the elastomer precursor. Then, an elastomer layer formed by the polymerization is separated from the master substrate and cut into pieces of predetermined size to thereby obtain a flexible photomask made of the elastomer according to the present invention.

The elastomer precursor for photomask formation may be selected from various types of commercially available materials. For example, a PDMS photomask can be made with a PDMS precursor that is mixed with Sylgard 184 (manufactured by Dow Corning) and a crosslinking agent at a ratio of 9:1 may be used. Type of the crosslinking agent is not limited, and any crosslinking agents commonly known in the art can be used to make the flexible photomask.

According to the present invention, an opaque layer may be formed on a flexible photomask. The opaque layer may be formed on depressions 37 [symbol] or prominences 38 [symbol] of the flexible photomask and a detailed description thereof will now be described.

First, a method for forming an opaque layer on depressions 37 [symbol] of a flexible photomask includes making a patterned flexible photomask as described above, depositing a metal on the entire area of a patterned surface of the photomask, and removing a metal layer formed on prominences 38 [symbol] of the photomask.

In more detail, first, a flexible photomask made by polymerizing an elastomer precursor on a patterned master substrate is prepared. Then, gold, palladium, chromium, etc. is deposited to a thickness of about 1 nm to 500 nm on a patterned surface of the photomask by thermal deposition, e-beam deposition, etc. At this time, the metal layer is formed on the entire area of the patterned surface of the photomask. Then, a metal layer formed on prominences 38 [symbol] of the photomask is removed by cold-welding technique using a strong metal-metal adhesion at room temperature or nanotransfer printing technique using a chemical bond. The cold-welding technique is a method that can be used to make a strong metal-metal adhesion when the metals do not have oxidized layers and have high work function. In the nanotransfer printing technique, alkane dithiol is applied on the surface of the promieneces 38, and is chemically bound to a metal layer formed on prominences 38 [symbol] of a photomask. A second metal layer is contacted to the alkane dithiol. Therefore the second metal layer is bonded to the metal layer of the prominences through the alkane dithiol. Then, the metal layer formed on the prominences 38 [symbol] of the photomask is removed by transfer or lift-off method.

In the case of removing the metal layer formed on the prominences 38 [symbol] of the photomask by cold-welding method, first, an adhesive layer made of Ti, etc. is formed on a silicon wafer, a glass substrate, etc. Then, a metal layer is formed on the adhesive layer using the same material as a metal layer to be removed and then is contacted to the metal layer of the photomask. At this time, the two metal layers are bonded together. When lift-off is performed, the metal layer formed on the prominences 38 [symbol] of the photomask is separated from the photomask by a strong tension of the adhesive layer. As a result, there is obtained a flexible photomask in which a metal layer remains only on depressions 37 [symbol] of the photomask.

In the case of removing the metal layer formed on the prominences 38 [symbol] of the photomask by nanotransfer printing method, an alkane dithiol based compound is applied to the metal layer formed on the prominences 38 [symbol] of the photomask to induce adhesion with the metal layer. Another thiol terminal of the alkane dithiol is bound to another metal layer. Then, when transfer or lift-off is performed, the metal layer formed on the prominences 38 [symbol] of the photomask, which is bonded to another metal layer through alkane dithiol, is removed.

Hitherto, a method of forming an opaque layer only on depressions 37 [symbol] of a patterned surface of a flexible photomask according to the present invention has been described. Hereinafter, a method of forming an opaque layer only on prominences 38 [symbol] of a patterned surface of a flexible photomask according to the present invention will be described.

First, a viscous organic material layer, for example, a polymer layer, a carbon black layer, or a silver paste layer is contacted to only prominences 38 [symbol] of a patterned surface of a flexible photomask manufactured as described above. At this time, the viscous organic material adheres to the prominences 38 [symbol] of the patterned surface forming an organic material layer. This process completes a flexible photomask in which an opaque layer is formed only on prominences 38 [symbol] .

For photomasks manufactured by the method described above, the same material used to make the basic mask layer could be also used to make the surface pattern. A surface pattern and a basic mask layer of a photomask, however, may also be made of different materials.

In order to make a photomask with a metal or an organic material pattern, a metal or an organic material is vacuum-deposited to a thickness of 1 nm to 500 nm, preferably 5 nm to 100 nm on a flat elastomer layer using a shadow mask.

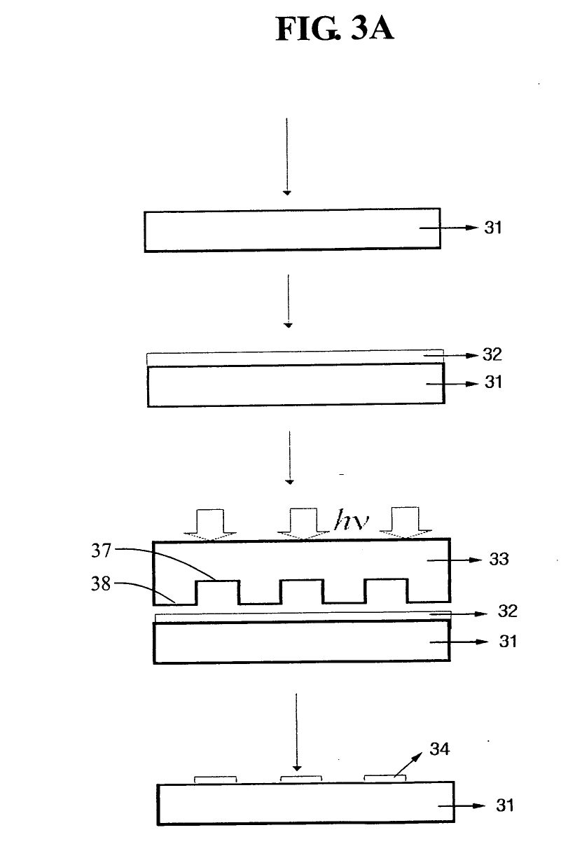

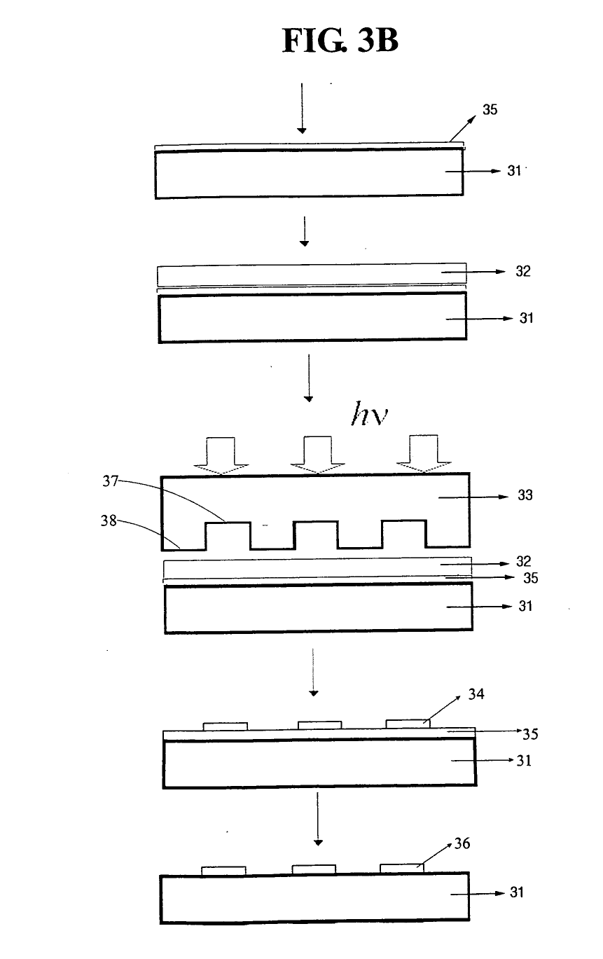

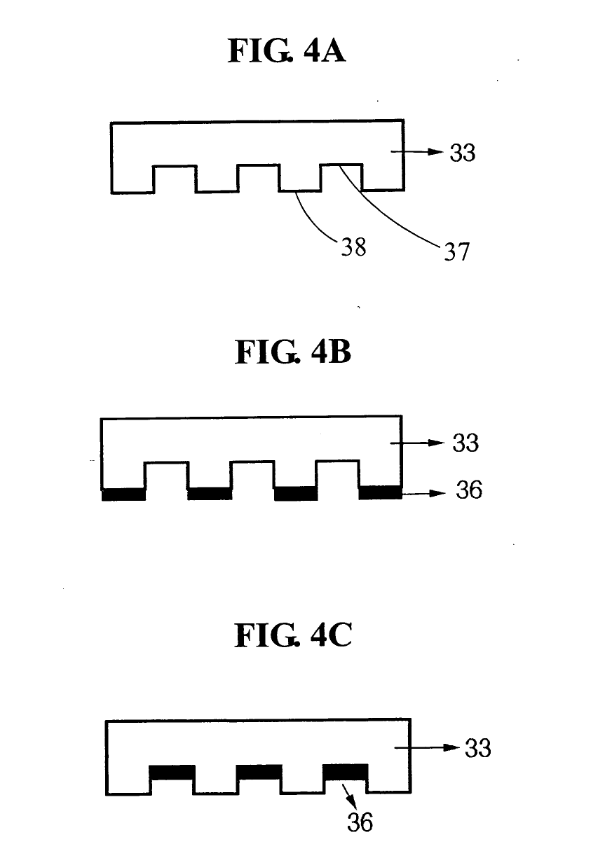

A method for micropatterning using a flexible photomask manufactured as described above will now be described with reference to FIGS. 3A and 3B.

Referring to FIG. 3A, a photoresist layer 32 is formed on a base substrate 31. Then, the photoresist layer 32 contacts a patterned surface of a flexible photomask 33 manufactured as described above, and ultraviolet light is exposed to the photoresist layer 32 through the photomask 33 to form a photoresist pattern pattern 34. Alternatively, referring to FIG. 3B, a metal layer 35 for pattern formation is selectively formed on a base substrate 31 and a photoresist layer 32 is formed on the metal layer 35. Then, the photoresist layer 32 contacts to a patterned surface of a flexible photomask 33 manufactured according to the principles of the present invention. After an exposure process, a photoresist pattern 34 is formed on the metal layer 35. The metal layer 35 is etched and a photoresist pattern 34 is removed, forming a metal pattern 36 on the base substrate 31.

In either types of the photomask described above, a transmissive mold-type photomask with a depression-prominence surface pattern or a photomask in which surface depressions or prominences are selectively coated with an opaque material, the prominences 38 make complete contact with a photoresist via a Van der Waals force but the depressions 37 are not contacted to the photoresist. In this case, when an appropriate amount of ultraviolet light is irradiated to a negative photoresist layer, a photoresist pattern which is the same as the pattern of the depressions of a photomask is formed. On the other hand, when an appropriate amount of ultraviolet light is irradiated to a positive photoresist, photoresist portions corresponding to depressions of a photomask are removed in a developing process and the remaining photoresist portions form a photoresist pattern. In the case of using a flexible photomask which has depressions and prominences but no opaque layer, photoresist portions corresponding to the depressions of the photomask remain (negative photoresist) or are removed (positive photoresist). In the case of using a flexible photomask in which depression or prominences are selectively coated with an opaque layer, photoresist portions corresponding to opaque layer-free photomask portions are left or are removed depending on the type of the photoresist. In the case of using a photomask in which a metal or organic material pattern is formed on a flat surface of an elastomer mold, photoresist portions corresponding to transparent photomask portions, where there is no metal or organic material pattern, are left (negative photoresist) or are removed (positive photoresist) through a developing process.

When a fine pattern is formed using a flexible photomask manufactured according to the principles of the present invention as described above, there is no gap between a photoresist layer 32 and prominences 38 of a patterned surface of the photomask 33. Furthermore, a molecular interaction between the photomask and the photoresist layer via a Van der Waals force provides complete contact between the photomask and the photoresist layer. In addition, since the photomask is made of a flexible material, a flexible substrate can be used. Therefore, a pattern 36 can be easily formed on a flexible substrate without causing defects such as cracks on an interface between a metal layer 35 and a photoresist layer 32.

A base substrate 31 used for fine pattern formation may be made of glass, plastic, rubber, elastomer, etc. In particular, it is preferable to use a base substrate made of a flexible material such as polyethylene terephthalate, polyethylene naphthalate, polyvinylalcohol, and polydimethylsiloxane.

A metal layer 35 used for fine pattern formation may include an adhesive promoter layer. In this case, it is preferable that the metal layer includes a first layer made of Ti or Cr with a thickness of 0.5 nm to 10 nm, more preferably 1 nm to 3 nm, and a second layer made of Au, Pd, Ag, or Pt with a thickness of 5 nm to 100 nm, more preferably 5 nm to 20 nm. If the thickness of the first layer is less than 0.5 nm, an adhesion may be weakened. On the other hand, the first layer with a thickness above 10 nm is economically unpreferable. If the thickness of the second layer is less than 5 nm, application to an electronic device such as an electrode may be difficult due to low conductivity. If it exceeds 100 nm, operation time for a wet etching may be increased and a poor edge pattern maybe obtained.

The flexible photomask of the present invention can be used for manufacturing of microelectronic devices such as semiconductor devices and display devices by adapting the micropatterning method described above. In particular, as the demands of flexible display devices increase, the demands for the flexible photomask will be also increased. For example, when a conductive material is patterned on a flexible substrate using a patterned flexible photomask according to the present invention, the above-described photolithography process can be used.

In particular, the use of the thus obtained pattern as an electrode enables to manufacture a flexible organic electroluminescent (EL) device. Hereinafter, a flexible organic EL device will be described in more detail.

FIGS. 8 through 11 illustrate organic EL devices according to embodiments of the present invention. Referring to FIG. 8, an organic EL device according to an embodiment of the present invention has a sequentially stacked structure of a substrate 41, a transparent electrode 42, an organic layer 44, and a metal electrode 43.

Generally, a driving mechanism of an organic EL device includes injection of holes and electrons from electrodes into an organic layer, electronic excitation by recombination of the holes and the electrons, emission from the excited state, etc. An organic EL device has the structure where an organic layer is interposed between two electrodes as described above. An organic EL device including a combined stacked structure of an emission layer and a charge transport layer as an organic layer exhibits more excellent device characteristics than an organic EL device including only an emission layer as an organic layer. In an organic EL device including a combined stacked structure of an emission layer and a charge transport layer as an organic layer, appropriate combination of a light-emitting material and a charge transport material reduces an energy barrier when charges of electrodes are injected to the organic layer. Furthermore, since the holes and electrons injected from the electrodes are contained in the emission layer by the charge transport layer, the density of the holes and electrons in the organic layer is balanced.

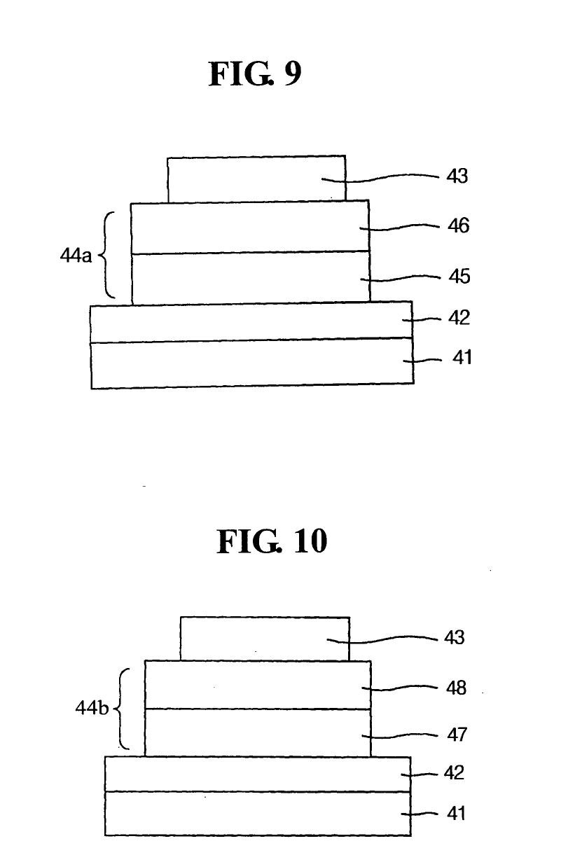

In this regard, the organic layer may include electron transport layer/emission layer/hole transport layer, electron transport layer/hole transport-emission layer, or hole transport layer/electron transport-emission layer, as shown in FIGS. 9 through 11. Here, a hole transport material that can be used for a hole transport layer or a hole transport-emission layer may be at least selected from carbazole derivatives, arylamine derivatives, phthalocyanine compounds, and triphenylene derivatives. An electron transport material that can be used for an electron transport layer or an electron transport-emission layer may be a quinoline derivative compound, a quinoxaline derivative compound, a metal complex, or a nitrogen-containing aromatic compound. A material that can be used for an emission layer may be selected from low molecular weight compounds or polymers such as phenylenes, phenylenevinylenes, thiophenes, and fluorenes, metal complexes, and nitrogen-containing aromatic compounds.

In detail, as described above, the organic EL device shown in FIG. 8 has a sequentially stacked structure of the substrate 41, the transparent electrode (anode) 42, the organic layer 44, and the metal electrode (cathode) 43. The substrate 41 is used for device formation and may be made of a material commonly known in the art, for example, glass, plastic, rubber, elastomer, etc. The substrate 41 may also be made of a flexible material such as polyethylene terephthalate, polyethylene naphthalate, polyvinylalcohol, polydimethylsiloxane, polycarbonate, polyester, polyestersulfonate, polysulfonate, polyacrylate, fluorinated polyimide, fluorinated resin, polyacryl, polyepoxy, polyethylene, polystyrene, polyvinylchloride, polyvinylbutyral, polyacetal, polyamide, polyamideimide, polyetherimine, ppolyphenylenesulfide, polyethersulfone, polyetherketone, polyphthalamide, polyethernitrile, polybenzimidazole, polymethyl(meth)acrylate, polymethacrylamide, epoxy resin, phenol resin, melamine resin, urea resin, nitrile rubber, arylic rubber, polybutadiene, polyisoprene, butyl rubber, or poly(styrene-co-butadiene). The transparent electrode (anode) 42 may be made of indium tin oxide (ITO), indium zinc oxide (IZO), zinc dioxide (SnO₂), etc, and the metal electrode (cathode) 43 may be a patterned metal electrode obtained by a micropatterning method according to the present invention. The organic layer 44 may be a monolayered or multilayered structure including a known light-emitting material. The organic layer 44 may also include Alq₃, rubrene, etc.

An organic EL device shown in FIG. 9 has a sequentially stacked structure of a substrate 41, a transparent electrode (anode) 42, an organic layer 44a, and a metal electrode (cathode) 43. The organic layer 44a has a stacked structure of a hole transport layer 45 and an electron transport-emitting layer 46. The substrate 41, the transparent electrode (anode) 42, and the metal electrode (cathode) 43 are the same as mentioned above. The hole transport layer 45 may be made of a single or a mixture of two or more of the commonly known hole transport materials, for example, 4,4-bis[N-(1-naphthyl)-N-phenyl-amine]biphenyl (α-NPD), N,N-diphenyl-N,N-bis(3-methylphenyl)-1,1-biphenyl-4,4-diamine (TPD), and poly(N-vinylcarbazole) (PVCz). The hole transport layer 45 may be a single layer or a mutiple layer. In the case of the multiple layer, each layer could be made of different material. The electron transport-emitting layer 46 may be made of a single or mixture of two or more of the commonly known electron transport materials, for example Alq₃, rubrene, etc. When needed, to enhance device characteristics such as efficiency and lifetime, a hole injection layer or an anode buffer layer made of copper phthalocyanine may be interposed between the transparent electrode (anode) 42 and the hole transport layer 45, and an electron injection layer or a cathode buffer layer made of LiF, BaF2, CsF₂, LiO₂, BaO, etc. may be interposed between the metal electrode (cathode) 43 and the electron transport-emitting layer 46.

An organic EL device shown in FIG. 10 has a sequentially stacked structure of a substrate 41, a transparent electrode (anode) 42, an organic layer 44b, and a metal electrode (cathode) 43. The organic layer 44b has a stacked structure of a hole transport-emitting layer 47 and an electron transport layer 48. The substrate 41, the transparent electrode (anode) 42, and the metal electrode (cathode) 43 are the same as mentioned above. The electron transport layer 48 may be made of a single or a mixture of two or more of the commonly known electron transport materials such as Alq₃, rubrene, polyquinoline, or polyquinoxaline. The electron transport layer 48 may also be a single layer or a multiple layer. In the case of the multiple layer, each layer could be made of different material. When needed, to enhance device characteristics such as efficiency and lifetime, a hole injection layer or an anode buffer layer made of copper phthalocyanine may be interposed between the transparent electrode (anode) 42 and the hole transport-emitting layer 47, and an electron injection layer or a cathode buffer layer made of LiF, BaF₂, CsF₂, LiO₂, BaO, etc. may be interposed between the metal electrode (cathode) 43 and the electron transport layer 48.

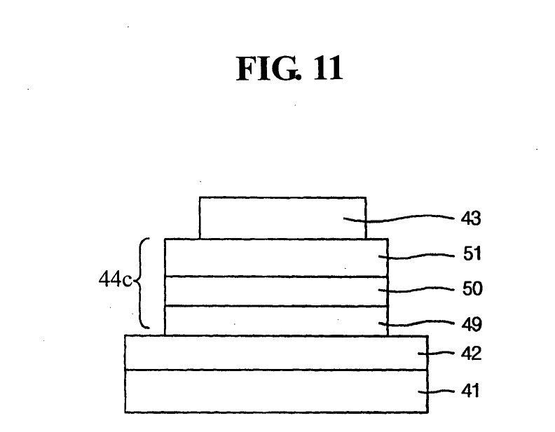

An organic EL device shown in FIG. 11 has a sequentially stacked structure of a substrate 41, a transparent electrode (anode) 42, an organic layer 44c, and a metal electrode (cathode) 43. The organic layer 44c has a stacked structure of a hole transport layer 49, an emission layer 50, and an electron transport layer 51. The substrate 41, the transparent electrode (anode) 42, and the metal electrode (cathode) 43 are as mentioned above. The hole transport layer 49 may be made of a single or a mixture of two or more of the commonly known hole transport materials, for example a-NPD, TPD, or PVCz. The hole transport layer 49 may also be a single layer or a multiple layer. In the case of the multiple layer, each layer could be made of different material. The electron transport layer 51 may be made of a single or a mixture of two or more of the commonly known electron transport materials such as Alq₃ and rubrene, and may be a single or multiple layer being made of the same or different material. When needed, to enhance device characteristics such as efficiency and lifetime, a hole injection layer or an anode buffer layer made of copper phthalocyanine may be interposed between the transparent electrode (anode) 42 and the hole transport layer 49, and an electron injection layer or a cathode buffer layer made of LiF, BaF₂, CsF₂, LiO₂, BaO, etc. may be interposed between the metal electrode (cathode) 43 and the electron transport layer 51. A material that can be used for the emission layer 50 may be selected from low molecular weight compounds; polymers such as phenylenes, phenylenevinylenes, thiophenes, and fluorenes; metal complexes; and aromatic compounds containing nitrogen.

The above-described organic EL devices shown in FIGS. 8 through 11 according to the present invention are driven by applying a voltage to the anode 42 and the cathode 43. The voltage is generally a direct current voltage but may also be a pulse or alternating current voltage.

Hereinafter, the present invention will be described more specifically with reference to the following examples. The following examples are for illustrative purposes and are not intended to limit the scope of the invention.

### EXAMPLE 1

### Manufacturing of a Flexible Photomask

A glass master substrate was prepared by forming a pattern on the substrate using a common photolithography process. The master substrate was placed on a petri dish in a manner that the pattern of the substrate faced upward, and then a PDMS precursor (Sylgard 184, Dow Corning) and a crosslinking agent were blended at a ratio of 9:1 in weight, and the mixture was applied to the top of the master substrate in the petri dish. Then, the mixture was cured at 80° C. for 2 hours to induce polymerization. When the polymerization was completed, an PDMS photomask obtained during the polymerization process was separated from the master substrate and cut into pieces of desired size to thereby obtain a flexible photomask made of PDMS.

### EXAMPLE 2

### Manufacturing of a Flexible Photomask with a Metal Layer (Cold Welding Method)

To form a metal layer as an opaque layer on depressions of the PDMS photomask manufactured in Example 1, Au was deposited to an average thickness of 30 nm on the entire surface of the PDMS photomask by e-beam deposition. Separately, an adhesive layer made of Ti was deposited to a thickness of 2 nm on a silicon wafer and then Au was deposited to a thickness of 30 nm on the adhesive layer. The Au layer of the photomask contacted the Au layer on the silicon wafer. Adhesion between the two Au layers was completed within 30 seconds. Then, the PDMS photomask was separated from the silicon wafer to selectively remove only the Au layer on prominences of the photomask, resulting in a PDMS photomask in which the Au layer was formed only on the depressions.

### EXAMPLE 3

### Manufacturing of a Flexible Photomask with a Metal Layer (Nanotransfer Printing Method)

To form a metal layer as an opaque layer on depressions of the PDMS photomask manufactured in Example 1, Au was deposited to an average thickness of 30 nm on the entire surface of the photomask by e-beam deposition. An octane dithiol solution (5 mM) was applied to the prominences of the PDMS photomask on which the Au layer was formed, so that an end functional group of the octane dithiol was bound to the Au layer. Separately, an adhesive layer made of Ti was deposited to a thickness of 2 nm on a silicon wafer and then Au was deposited to a thickness of 30 nm on the adhesive layer. The Au-coated PDMS photomask contacted the silicon wafer so that the other end functional group of the octane dithiol was bound to the silicon wafer. Then, the PDMS photomask was separated from the silicon wafer to selectively remove only the Au layer on prominences of the photomask, resulting in a PDMS photomask in which the Au layer was formed only on the depressions.

### EXAMPLE 4

### Manufacturing of a Flexible Photomask with a Carbon Black Layer

To form a carbon black layer as an opaque layer on prominences of the PDMS photomask manufactured in Example 1, a viscous carbon black layer was thinly coated on a substrate and then immediately contacted to the prominences of the PDMS photomask so that the viscous carbon black layer was coated on the prominences of the photomask. The photomask was dried to thereby obtain a PDMS photomask in which the carbon black layer was formed only on the prominences.

### Example 5

### Pattern Formation on a Flexible Substrate

A photoresist layer was formed to a thickness of 400 nm on a PDMS substrate by a spin casting method. The flexible photomask manufactured in Example 1 was placed on the photoresist layer, exposed to light with an intensity of 100 μW/cm², and developed with a KOH solution, to thereby obtain a photoresist pattern.

### EXAMPLE 6

### Metal Pattern Formation on Flexible Substrate

A Ti layer as an adhesive promoter and an Au layer were sequentially formed to a thickness of 2 nm and 20 nm, respectively, on a PDMS substrate. Then, a photoresist layer was formed to a thickness of 400 nm on the Au layer by a spin casting method. The flexible photomask manufactured in Example 1 was placed on the photoresist layer, exposed to light with light intensity of 100 μW/cm², and developed with a KOH solution, to form a photoresist pattern. Then, the Au layer was etched with a KI solution and the photoresist pattern was removed with acetone to thereby obtain an Au pattern on the PDMS substrate.

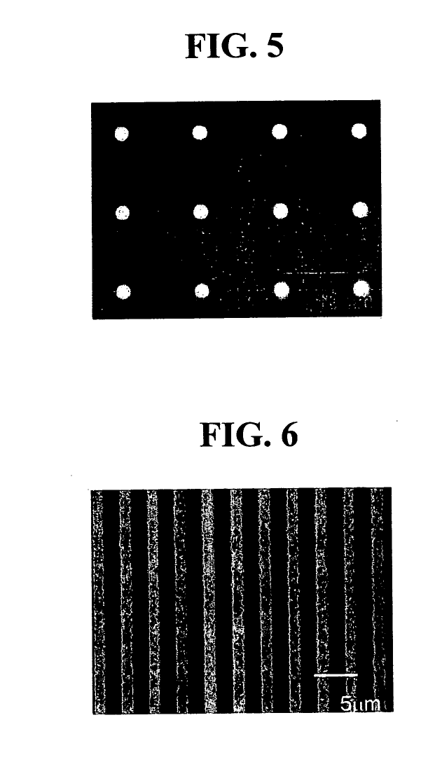

Optical microscopic images of the metal pattern obtained in the above process are shown in FIGS. 5 and 6. Referring to FIGS. 5 and 6, the metal pattern exhibits high pattern resolution, good uniformity, and little defects such as cracks.

### EXAMPLE 7

### Manufacturing of an Organic EL Device

Electrodes for an organic EL device were manufactured according to the method of Example 6.

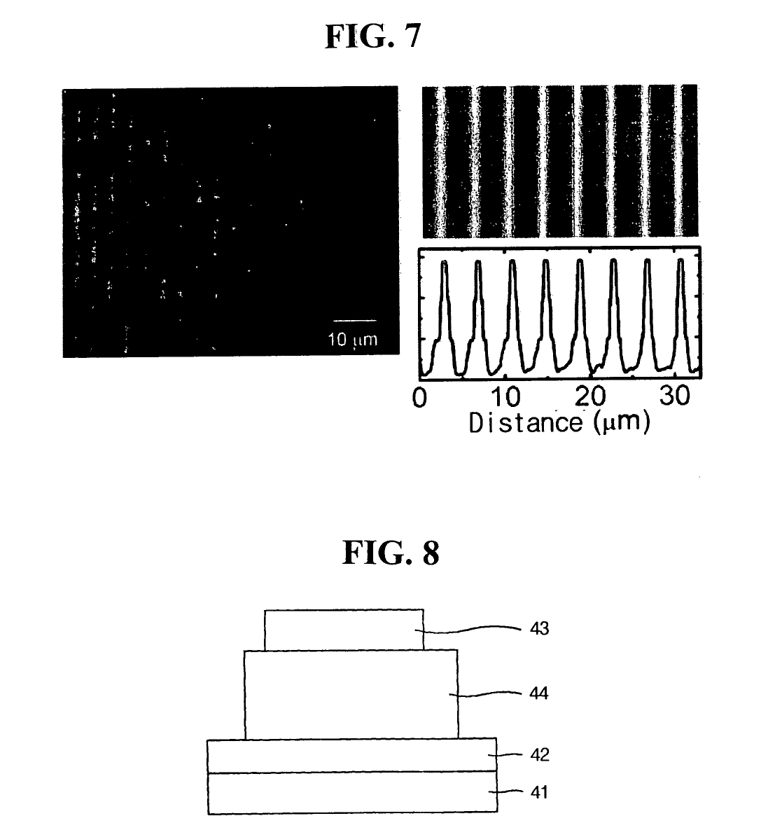

A PDMS layer was formed on a base glass. Then, a Ti layer as an adhesive promoter was deposited to a thickness of 2 nm on the PDMS substrate and then an Au layer was formed to a thickness of 20 nm on the Ti layer. Then, a photoresist layer was formed to a thickness of 500 nm on the Au layer by spin casting method. The flexible photomask manufactured in Example 1 was placed on the photoresist layer, exposed to light with light intensity of 200 μW/cm² for 10 seconds, and developed with a KOH solution, to form a photoresist pattern. Then, the Au layer was etched with a KI solution and then the photoresist pattern was removed with acetone, to thereby obtain an Au pattern on the PDMS substrate. An optical microscopic image of the Au pattern is shown in the upper right side of FIG. 7. The lower right side of FIG. 7 shows intensity measurement data of the Au pattern.

Separately, an ITO layer was formed on a glass substrate and then an emission layer was formed on the ITO layer.

The Au patterned PDMS substrate was attached to the emission layer on the glass substrate via a Van der Waals force to complete an organic EL device. Referring to the left side of FIG. 7, an EL pattern with a linewidth of 800 nm is shown.

### COMPARATIVE EXAMPLE 1

### Pattern Formation on a Flexible Substrate Using a Hard Photomask

A photoresist pattern was obtained in the same manner as described in Example 5 with the use of a conventional hard photomask instead of the flexible photomask disclosed in the present invention.

An optical microscopic image of the photoresist pattern showed that pattern quality was lowered due to cracks etc.

### COMPARATIVE EXAMPLE 2

### Manufacturing of an Organic EL Device Using a Hard Photomask

An electrode for an organic EL device was manufactured in the same manner as in Example 6 with the use of a conventional hard photomask instead of the flexible photomask.

When examined with a multimeter and an I-V meter (a current-voltage characteristic measurement instrument), the device showed poor current flow characteristics due to cracks produced on the patterned surface, etc.

The present invention provides a flexible photomask for photolithography. The photomask exhibits a strong adhesion with a photoresist layer, and prevents pattern defects such as cracks from being generated even when a flexible substrate is used. Thus, patterning using the photomask can enhance pattern uniformity, quality, and resolution. Therefore, the photomask is particularly useful in manufacturing of electrodes of flexible display devices such as an organic EL device. In addition, the photomask can also be used in manufacturing of a semiconductor device.

What is claimed is:

1. A photomask comprising:
a mask layer made of a flexible material; and
a surface pattern formed on one side of said mask layer, said surface pattern comprising a plurality of depressions and prominences.

2. The photomask of claim 1, wherein said flexible material is a light-transmissive elastomer.

3. The photomask of claim 2, wherein the light-transmissive elastomer has a glass transition temperature of less than room temperature.

4. The photomask of claim 2, wherein the light-transmissive elastomer is at least one selected from the group consisting of polydimethylsiloxane, nitrile rubber, acrylic rubber, polybutadiene, polyisoprene, butyl rubber, and poly(styrene-co-butadiene).

5. The photomask of claim 1, said surface pattern being made of a light-transmissive elastomer or an opaque material.

6. The photomask of claim 5, the opaque material being selected from the group consisting of one of a metal and an organic material.

7. The photomask of claim 6, the organic material being selected from the group consisting of a low molecular weight compound, a polymer, a carbon black, and a silver paste.

8. The photomask of claim 6, wherein a light absorption band of the organic material is in the range from 200 nanometers to 450 nanometers.

9. The flexible photomask of claim 6, the metal being selected from the group consisting of gold, silver, chromium, aluminum, nickel, platinum, palladium, titanium, and copper.

10. The photomask of claim 5, wherein thickness of the surface pattern being made of the opaque material is in the range from 1 nanometer to 500 nanometers.

11. The photomask of claim 1, wherein thickness of the surface pattern is in the range from 100 nanometers to 1000 nanometers.

12. The photomask of claim 1, further comprising an opaque layer being formed on a surface of one of said depressions and said prominences.

13. The photomask of claim 12, said opaque layer being made of a material selected from the group consisting of a metal and an organic material.

14. The photomask of claim 13, said organic material being selected from the group consisting of a low molecular weight compound, a polymer, a carbon black, and a silver paste.

15. The photomask of claim 13, wherein light absorption band of said organic material layer is in the range from 200 nanometers to 450 nanometers.

16. The photomask of claim 13, said metal being selected from the group consisting of gold, silver, chromium, aluminum, nickel, platinum, palladium, titanium, and copper.

17. The photomask of claim 12, wherein thickness of said opaque layer is in the range from 1 nanometer to 500 nanometers.

18. A method of manufacturing a photomask comprising:
preparing a patterned master substrate;
applying a mixture of an elastomer precursor and a crosslinking agent to the master substrate;
polymerizing the mixture for forming a mask; and
separating the mask from the master substrate.

19. The method of claim 18, further comprising:
depositing a metal on a patterned surface of the mask; and
selectively removing a metal layer formed on the patterned surface of the mask.

20. The method of claim 18, further comprising
applying an adhesive material to prominences of a patterned surface of the mask, the adhesive material being selected from the group consisting of an adhesive polymer solution, a carbon black paste, and a silver paste.

21. A method of manufacturing a photomask comprising:
forming a elastomer layer;
contacting a shadow mask to the elastomer layer; and
applying a pattern material to the shadow mask to form a pattern on the elastomer layer, the pattern material being selected from the group consisting of a metal and an organic material.

22. The method of claim 21, the elastomer layer being made of a silicon-based elastomer.

23. The method of claim 21, said applying the pattern material being performed by a vacuum deposition.

24. A micropatterning method comprising:
forming a photoresist layer on a base substrate;
contacting a patterned surface of a flexible photomask to the photoresist layer, the flexible photomask being made of light-transmissive elastomer; and
forming a photoresist pattern by exposing light to the photomask.

25. The micropatterning method of claim 24, further comprising:
forming a metal layer on the base substrate before said forming the photoresist layer;
etching the metal layer; and
removing the photoresist pattern.

26. The micropatterning method of claim 24, wherein the photoresist pattern is formed by removing regions of photoresist layer corresponding to depressions of the flexible photomask.

27. The micropatterning method of claim 24, wherein the photoresist pattern is formed by removing regions of photoresist layer corresponding to prominences of the flexible photomask.

28. The micropatterning method of claim 24, the base substrate being made of a material selected from the group consisting of glass, plastic, rubber, and elastomer.

29. The micropatterning method of claim 28, the base substrate being made of a silicon-based elastomer.

30. The micropatterning method of claim 25, wherein the metal layer comprises an adhesive promoter layer.

31. The micropatterning method of claim 30, the adhesive promoter layer being made of a material selected from the group consisting of titanium and chromium, the thickness of the adhesive promoter layer being between 1 nanometer and 5 nanometers.

32. The micropatterning method of claim 25, the metal layer being made of a material selected from the group consisting of gold, silver, aluminum, palladium, and platinum.
